(19) United States
(12) Patent Application Publication
(10) Pub. No.: US 2023/0146773 A1
(43) Pub. Date: May 11, 2023

(54) GaAs Based Photodetectors Using Dilute Nitride for Operation in O-band and C-bands

(71) Applicant: NanoGrass Solar LLC, (US)

(72) Inventors: Bahram Nabet, Philadelphia, PA (US); Pouya Dianat, Philadelphia, PA (US); Michel Francois, Wyncote, PA (US); Fabio Quaranta, Lecce (IT); Adriano Cola, Lecce (IT)

(73) Assignee: NanoGrass Solar LLC, Philadelphia, PA (US)

(21) Appl. No.: 17/980,761

(22) Filed: Nov. 4, 2022

Related U.S. Application Data
(60) Provisional application No. 63/275,983, filed on Nov. 5, 2021.

(51) Int. Cl. H01L 31/112; H01L 31/0232; H01L 31/0304; H01L 31/0392; H01L 31/18

(52) U.S. Cl. CPC H01L 31/1123; H01L 31/02327; H01L 31/03046; H01L 31/0392; H01L 31/1844

(57) ABSTRACT

Photodetectors are fabricated on GaAs substrate using dilute nitride technology for high speed-high-sensitivity operation for telecom and datacom applications for the wavelength ranges covering O-band (Original band: 1260 nm to 1360) to C-band (conventional band: 1530-1565 nm).

### CROSS-REFERENCE TO RELATED APPLICATION

This application claims the benefit of U.S. Provisional Patent Application Ser. No. 63/275,983, filed on Nov. 5, 2021, which is incorporated herein by reference in its entirety.

### BACKGROUND OF THE INVENTION

On-demand and reliable access to data are vital for 21^{st} century; Data centers, therefore, go through multiple layers of redundancy in order to ensure a 99.99999% reliable link for their customers. Such operations are energy hungry and electricity bills comprise ˜%30-40 of annual costs of data centers. Currently they consume ˜5% of the total energy grid. With an expected 1000× increase in the amount of data by 2025, this number is expected to rise. Communication networks face similar challenges. The backbone optical communication infrastructure is the workhorse of data transmission inter- and intra-data center. Energy efficient and high capacity optical systems are in great demand, but high in price and low in supply. The advent of Photonics Integrated Circuits (PICs) has provided an economical solution to the supply and demand problem. A PIC is comprised of multiple optical components such as modulators, lasers, detectors, multiplexers and demultiplexers, and attenuators, all integrated in a single chip”.

An important component in a PIC circuit is the photodetector device that converts optical information to electronic ones. We have previously demonstrated a new class of high speed opto-plasmonic photodetectors (OPPD) on GaAs substrate that operate in the 830 nm wavelength range, having very low dark current, a measure of noise that approaching zero; Lowest required bias (even zero volts) and energy usage; very high bandwidth exceeding 250 GHz; and very high sensitivity approaching thousands of photons. While this wavelength of operation is suitable for data communication over short distances, using multimode fibers, and is relatively cheap, tele-data communication within data centers, amongst base stations in wireless communication, for wide area networks (WANs) and long area networks (LANs) is performed in the more desirable wavelength of operation in 1310 and 1550 nm, the O-band and C-bands, respectively, where light absorption and dispersion in fiber optic cables is minimized.

Transmitter/receivers, transceivers, that operate in 1310 and 1550 ranges, are fabricated on InP substrates using a variety of compound semiconductors such as InGaAs, InGaP, InGaSb, InGaAsP and are much more costly than the alloys that are made on GaAs substrate. The recently developed dilute nitride technology, however, has shown that several alloys of ternary and quaternary compounds can be grown on GaAs using molecular beam epitaxy (MBE) or other growth techniques, which will have the bandgap that can be tuned from 830 nm to 1600 nm, hence operate in the wavelength range for O-band and C-bands, using small amounts of nitrogen in the compound, hence the name dilute nitride.

Photodetectors and lasers operating at 1310 and 1550 nm wavelengths have been previously demonstrated. Two major impediments, however, limit the performance of the dilute nitride based photodetectors. First, both PN junction— and its variants PIN, and Avalanche Photodiodes (APD)—and its metal-semiconductor-metal Photodiode (MSM-PD) and Schottky diodes made on dilute-nitride based devices suffer from relatively high dark current which limits their signal-to-noise ratios (SNR). Second, dilute nitride material built on GaAs have very 100-1000 times less electron mobility compared to the same material grown on InP. This means that their response speed if dependent on charge transport, is much longer compared to devices made on InP.

### BRIEF SUMMARY OF THE INVENTION

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

In one embodiment, the present invention is a photodetector comprising: a GaAs semi-insulating substrate; a GaAs buffer layer on top of the substrate; a plurality of alternating Bragg layers of AlAs and AlGaAs on top of the buffer layer; and a plurality of XxGaAsYy layers on top of the alternating layers, wherein Xx and Yy is one of nothing, Al, In, N, P, and Sb.

In another embodiment, the present invention is a photodetector comprising: a substrate; a buffer layer on top of the substrate; a Bragg layer on top of the buffer layer; a first Delta layer on top of the Bragg layer; at least one layer on top of the first Delta layer; an absorption layer on top of the at least one layer; a second Delta layer on top of the absorption layer; a barrier layer on top of the second Delta layer; and a cap layer on top of the barrier layer.

### BRIEF DESCRIPTION OF THE DRAWINGS

The accompanying drawings, which are incorporated herein and constitute part of this specification, illustrate the presently preferred embodiments of the invention, and, together with the general description given above and the detailed description given below, serve to explain the features of the invention. In the drawings:

FIG. 1 is a top plan view of an interdigitated metal-semiconductor-metal (MSM) optical detector according to the prior art

FIG. 2 is a scanning electron microscope image of the device of FIG. 1;

FIG. 3A is a graph of a time response to ˜400 fs light pulses at 830 nm wavelength with 54 μW optical power, at 0, 1, and 2V bias, with an inset normalized to peak showing 2.9 pico seconds (ps), 2.9 ps, and 2.5 ps full-width half-max (FWHM) pulse width, respectively, for the device of FIG. 1 with >8.5 um distance between the cathode and anode;

FIG. 3B is a graph of time response of a device with a 8.5 μm gap distance, but without 2D electron and 2D hole reservoirs, under 7, 9, and 15 V bias showing a FWHM of 50, 55, and 75 ps, respectively, with an inset showing time response of a device with similar geometry under the same conditions, all in the prior art;

FIG. 3C is a graph showing time responses for devices with 1.8 and 8.7 μm transit distances being nearly identical and independent of charge transport distance; in the prior art

FIG. 3D is a graph showing measured time response at various optical powers under 2 V bias showing high sensitivity in the prior art: at the lowest power, nearly 10,500 photons that are absorbed in the GaAs region produce the electric pulse consisting of −1500 electrons;

FIG. 4 is a schematic of a design with confined electron and hole gasses, 2DEG and 2DHG, respectively, with a dilute nitride (DN) light absorption layer sandwiched between them (2DEHG DN-MSM)two-dimensional electron hole gas dilute nitride device according to an exemplary embodiment of the present invention;

FIG. 5 is a schematic of a device with different positioning of confined electron and hole gasses (2DHEG DN-MSM) according to an alternative exemplary embodiment of the present invention;

FIG. 6 is a schematic of a 2DEHG device where the confined gasses are positioned in dilute nitride (2DEHG-DN) according to an exemplary embodiment of the present invention;

FIG. 7A is a table of layers of a barrier enhanced DN-MSM device according to an exemplary embodiment of the present invention;

FIGS. 8A-8I is a schematic view of an exemplary method of manufacturing a photodetector according to the present invention;

FIG. 9 is a top view photograph of an array of fabricated devices according to the present invention with one being probed for optoelectronic measurements;

FIG. 10 is a graph of current-voltage relation of a device according to the present invention under 1310 nm laser light showing sensitivity to this wavelength of light that is not possible to detect on GaAs substrate, and very low dark current, resulting in a high dynamic range; and

FIG. 11 is a graph of photocurrent spectra of devices of structures 100 and 300 and the structures of FIGS. 7A and 7B being compared, with all devices operating within the O-band, being formed on GaAs substrates which do not absorb light with wavelength higher that 830 nm.

### DETAILED DESCRIPTION

In the drawings, like numerals indicate like elements throughout. Certain terminology is used herein for convenience only and is not to be taken as a limitation on the present invention. The terminology includes the words specifically mentioned, derivatives thereof and words of similar import. The embodiments illustrated below are not intended to be exhaustive or to limit the invention to the precise form disclosed. These embodiments are chosen and described to best explain the principle of the invention and its application and practical use and to enable others skilled in the art to best utilize the invention.

Reference herein to “one embodiment” or “an embodiment” means that a particular feature, structure, or characteristic described in connection with the embodiment can be included in at least one embodiment of the invention. The appearances of the phrase “in one embodiment” in various places in the specification are not necessarily all referring to the same embodiment, nor are separate or alternative embodiments necessarily mutually exclusive of other embodiments. The same applies to the term “implementation.”

As used in this application, the word “exemplary” is used herein to mean serving as an example, instance, or illustration. Any aspect or design described herein as “exemplary” is not necessarily to be construed as preferred or advantageous over other aspects or designs. Rather, use of the word exemplary is intended to present concepts in a concrete fashion.

The word “about” is used herein to include a value of +/−10 percent of the numerical value modified by the word “about” and the word “generally” is used herein to mean “without regard to particulars or exceptions.”

Additionally, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more” unless specified otherwise or clear from context to be directed to a singular form.

Unless explicitly stated otherwise, each numerical value and range should be interpreted as being approximate as if the word “about” or “approximately” preceded the value of the value or range.

The use of figure numbers and/or figure reference labels in the claims is intended to identify one or more possible embodiments of the claimed subject matter in order to facilitate the interpretation of the claims. Such use is not to be construed as necessarily limiting the scope of those claims to the embodiments shown in the corresponding figures.

It should be understood that the steps of the exemplary methods set forth herein are not necessarily required to be performed in the order described, and the order of the steps of such methods should be understood to be merely exemplary. Likewise, additional steps may be included in such methods, and certain steps may be omitted or combined, in methods consistent with various embodiments of the present invention.

Although the elements in the following method claims, if any, are recited in a particular sequence with corresponding labeling, unless the claim recitations otherwise imply a particular sequence for implementing some or all of those elements, those elements are not necessarily intended to be limited to being implemented in that particular sequence.

In the present invention, the basic limitations of the prior aret are overcome by employing a planar MSM-PD top-illuminated device geometry, and constructing structured layers of heterojunctions around the dilute nitride material that a) reduce the dark current substantially, and, b) simultaneously achieve fast response.

A barrier enhancement layer is provided between the metal contacts and the semiconductor that will increase Schottky Barrier Height (SBH) and thus reduce dark current.

Heterojunctions are constructed and by proper choice of doping and layer thicknesses, two goals are achieved. First, confined mobile two-dimensional electron and hole gasses, 2DEG and 2DHG systems, respectively, are produced, which are placed lateral to the low mobility dilute nitride region which absorbs incident light signal. Second, by proper doping we landscape an internal electric field that modifies the trajectories of the electron-hole pairs (EHPs) produced by light is landscaped so that the EHPs do not have to travel long lateral distances to cathode and anode contacts, rather, the EHPs travel short vertical distances to either 2DEG or 2DHG and are collected once the EHPs reach these mobile cloud of charges.

Finally alternating layers of AlAs and GaAs and a Bragg resonant cavity are constructed that will recirculate the light in the absorption regions, thus increasing device responsivity while maintaining its fast speed of response

The present invention provides a high-performing dilute nitride (DN) photodetector for use in the tele/data communication infrastructure. The inventive photodetector operates at a six-times (6x) higher bandwidth and a ten-twenty times (10x-20x) lower optical power conditions as compared to a commonly used 40-GHz pin device.

The inventive opto-plasmonic detectors (OPDs) have the highest bandwidth and lowest noise characteristics of any photodetector, making them extremely well matched for use in tele/datacom and LiDAR systems. By employing charge density waves that, quite simply, propagate faster than conventional charge transport of electrons and holes, the photodetectors of the present invention accomplish an unparalleled level of performance. At the core of the invention is an uncomplicated epitaxial stack consisting of a two-dimensional electron gas (2DEG) and a two-dimensional hole gas (2DHG) separated by an absorption region. The inventors believe that this architecture has the highest potential of any photodetector technology to displace traditional p-i-n and avalanche photodiodes (APD) technologies. The present invention is directed to extend the operating wavelength of ultra-wide bandwidth, low noise devices from 830 nm to 1310/1550 nm. In doing so, the inventive detectors are built on 4 or 5-inch GaAs substrates and deliver similar performance at a much lower cost than conventional devices based on 3-inch InP substrates.

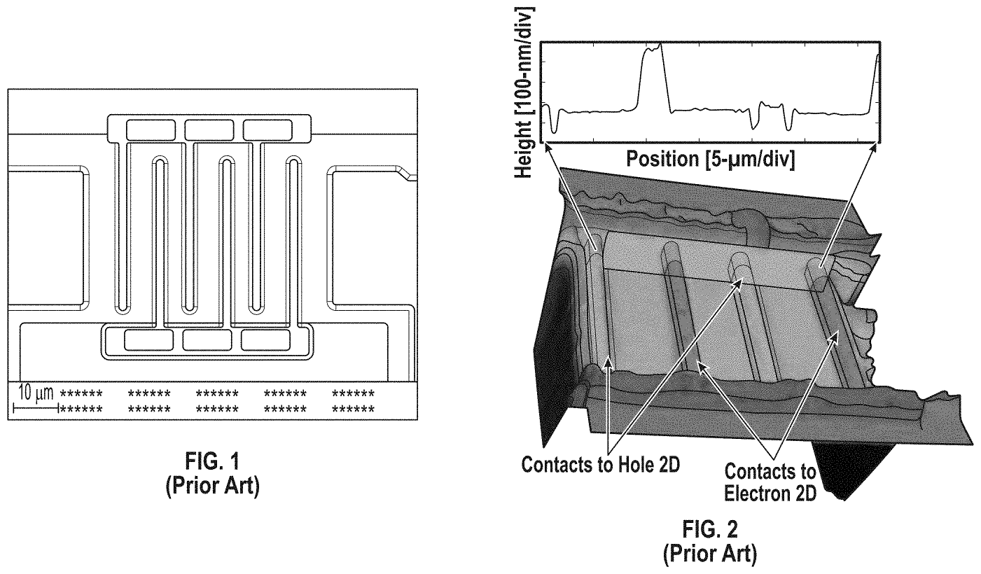

Deploying the inventive technology on 5-inch GaAs to 1310/1550 nm brings significant economic advantages, primarily due to the vastly increased substrate surface area—a factor of 9× when comparing InP to GaAs. Increased production of OPD chips on GaAs will not only lower the cost, but the barriers to integrating our photodetectors in telecommunication networks, LiDAR systems, transceivers in data centers and space-based communications. FIGS. 1 and 2 show a view of the baseline technology, which is a top illuminated low noise, high-speed photodetector operating at 830 nm, 240 GHz bandwidth and 9.5% quantum efficiency.

Traditional photodetectors operate under constant bias and accomplish o-e conversion by absorbing light in an intrinsic region of semiconductor and generating e-h pairs. The charge is collected in ohmic metal contacts and transmitted to external electronics. There are two major varieties of photodetectors: p-i-n devices which operate under relatively low bias (e.g., −3V) and have typical responsivity of 0.5-0.7 A per watt of detected light; APD devices operate under a higher bias (e.g., −20V) to induce impact ionization and provide responsivity with a gain of 9-10A/W. For decades, both types of devices have been workhorse platforms in telecommunications where p-i-n devices are more widely deployed than APDs.

High bandwidth p-i-n devices operating at 1550 nm—typically 100 GHz, which is the fastest commercially available device has costs that typically exceeds $22,000 per packaged unit, fiber coupled without onboard electronics. A great deal of this cost stems from the expensive substrate and epitaxy. However, it is possible to shift away from this traditional material system and detection approach—and achieve at least 200 GHz bandwidth by leveraging charge density waves.

The inventive OPDs leverage the physics of a collective of electronic charges, aka plasmonic waves, for detection and manipulation of optical signal arriving from an optical communication link e.g. fiber, to an electronic signal ready for processing. While competing methods of optical detection rely on transport of electrons, and therefore are fundamentally limited by the dynamics of individual charge transport, our method exploits the super-fast dynamics of collectives of electrons in the form of a propagating charge density, plasmonic, wave. In response to 40-femto-second pulses of (830 nm) coherent light, our photodetectors have exhibited response times as small as 2 ps, while the fastest competing technologies cannot go below 20 ps due to the limits imposed by charge transport. Circumventing this limitation by exploiting the collective behavior of electrons allows this 10× improvement in speed of response that is fundamentally different from other methods of light detection.

The wave motion in an electron gas medium has time constants of the order of the dielectric relaxation time of the medium which is proportional to the product of the medium's permittivity, εₛ, and resistivity, ρ, which for high charge densities is in tens of femtosecond range. On the other hand, time constants based on charged particle motion are much slower than these dielectric relaxation times; this is to be expected since the former can be an energy relaxation process, while the latter is due to real charge motion due to acceleration by the force of the electric field and deceleration due to scattering. Two-dimensional electron, and hole, gases in semiconductors are constructed to create reservoirs of charge which respond to (optical) excitation with speed and sensitivity that is not possible to obtain with a current flow model. Instead, this is analogous to detecting a drop of water in a pond by the wave it generates; a feat that is not possible to perform by detecting the change in current flow. As a result, a 400-fs perturbation by about 11,000 photons in an 8.5 μm device produces a less than 2.5-ps response which would take over 100 ps of it were based on charge transport.

Optoplasmonic Photodetector Device—The reservoirs of charge produced here are those with sheets of electrons and holes whose motion is confined to two dimensions rather than 3D motion that occurs in bulk semiconductors. The inventive layer structure incorporated confined 2DEG and 2DHG similar to those in a High Electron Mobility Transistors (HEMT). The wafer was grown by molecular beam epitaxy (MBE) on semi-insulating GaAs. After growth of a buffer layer, Al_{.3} Ga_{.7}As is lattice-match grown and p-type delta-doping is used to produce the 2DEHG with holes that can only move in the direction perpendicular to growth direction. A thin layer of GaAs which is a fraction of the wavelength of incident photons is grown to absorb light. Although the fundamental edge of absorption in GaAs is around 830 nm, it absorbs light in the solar spectrum; it can, however, be substituted by other material with absorption capability at required wavelengths. On top of this thin ˜100 nm absorption region another heterointerface with a wide gap material is grown so as to produce a 2D electron gas. The energy band diagram of this structure is calculated by self-consistent solution of Poisson and Schrodinger equations indicates existence of electron and hole distributions of relatively dense concentrations, ˜6.5×10¹¹ cm⁻² electrons and ˜2.2×10¹¹ cm⁻² holes.

Optical Properties—A scanning electron microscope image of the fabricated device is shown in FIGS. 1 and 2, with a cross-sectional cut demonstrating that the 2DEG and 2DHG are separately contacted by evaporation of metals forming blocking contacts. The current-voltage (I-V) relation in ambient room light (dark) and under continuous wave (CW) illumination by an 830-nm Ti:Sapphire laser at three different optical intensity levels are also shown in FIG. 1. The dark I-V shows currents below 100 pA when the contact to 2DHG is the cathode. The very low dark current observed here verifies that the blocking contacts maintain the confined reservoirs of charge under quasi equilibrium, with small amount of current flowing by thermionic emission. Had these contacts been Ohmic, as is the case for the source and the drain of a transistor, up to eight (8) orders of magnitude more current, in milliamps, would flow.

The device is illuminated with a laser light with an 830-nm wavelength that is absorbed in the—100 nm thick GaAs absorption layer which is sandwiched between two-dimensional sheets of electron and hole gas reservoirs. Without the 2DEG and 2DHG reservoirs the photogenerated carriers would be swept by the lateral electric field that is produced by the Schottky contacts in this structure and collected at the contacts. Here, however, there is a vertical electric field of ˜8V/μm which moves the optically generated electrons to the (top) 2DEG and the holes to the (bottom) 2DHG. FIG. 2 shows that the device is a very efficient optical detector with five (5) orders of magnitude current change caused by a 54μW optical excitation. It is also very sensitive, with 1.2 μW of light causing a current change by a factor of over 4000, as compared to the device in dark. In other experiments as low as 250 nW was detectable, limited by the electronic equipment.

Time Response—The dynamics of the response of these 2DEG and 2DHG micro plasma are probed by perturbing them with short, 400 femtosecond, pulses of light generated by the Ti:Sapphire laser with a center wavelength tunable from 750-1080 nm. Absorption of these pulses of light generates electron and hole pairs in the (˜100 nm thick) GaAs region. Subject to the large vertical electric field, electrons and holes separate and drift, respectively, towards the 2DEG and 2DHG reservoirs which laterally extend the long (>8 μm) distance between the contacts. High speed testing is performed with an electro-optic sampling (EOS) system.

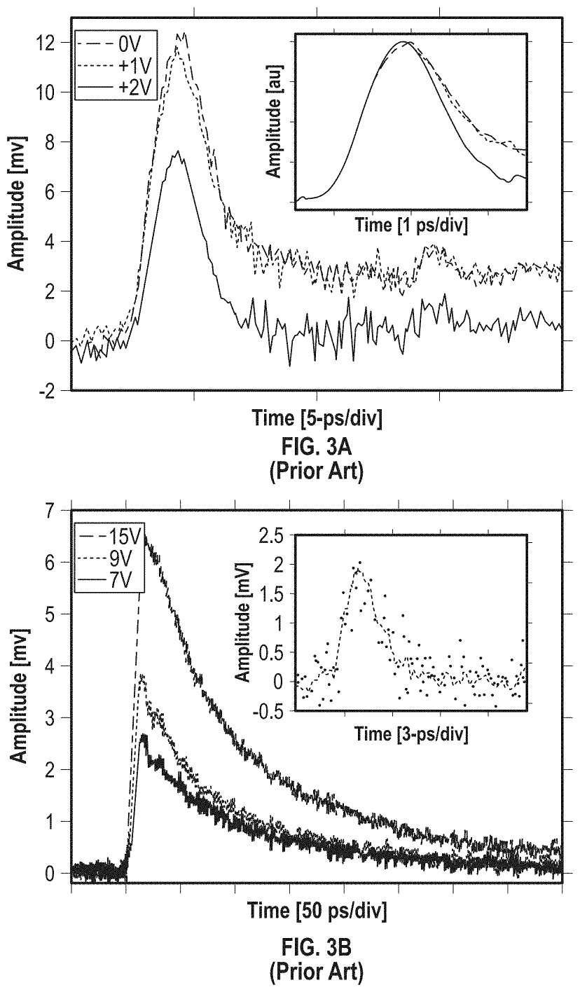

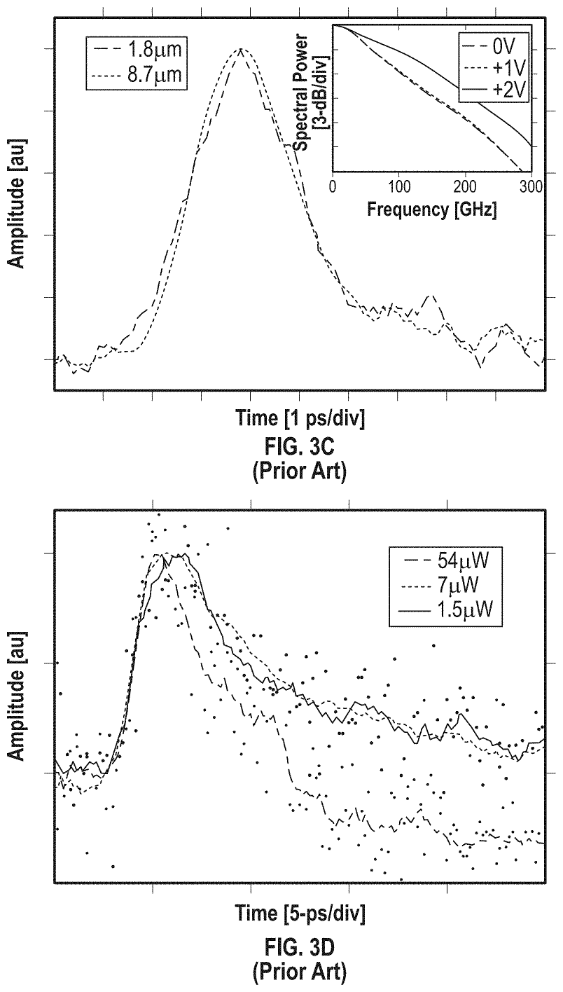

The measured time response to ˜100 fs pulses with average 54 μW optical power and applied biases of 0, 1, and 2 V at 830 nm is shown in FIG. 3A. Data normalized to peak value in the inset of the FIG. shows pulse width, given as the Full-Width at Half-Maximum (FWHM), values of 2.9, 2.9, and 2.4 ps, respectively. The 1.4-ps rise time of the response is longer than the EOS system response and is potentially due to transmission line dispersion occurring from the electrical pulse's 250 μm propagation distance. This would suggest an even faster intrinsic device response by up to 0.4 ps. This short response cannot be due to transit of electrons which, in the best case of saturation drift velocity of 10⁷ cm/s would be around 80 ps, with holes taking nearly ten times longer, depending on the electric field intensity.

To accentuate this point, a device with 8 μm separation of contacts, and similar layer structure, but without 2DEG and 2DHG was fabricated and tested. The temporal pulse width for 11 μW incident power at 830 nm, as shown in FIG. 3B, is 50, 55, and 75 ps (FWHM) for respectively, 7, 9, and 15V bias—the larger bias was chosen to assure carrier sweep out and a fair comparison. The response tail—the fall time—which depends on the transport and collection of slow-moving carriers, is seen to be as high as 200-250 ps in this device. This may be contrasted with the response shown in the inset of FIG. 3B for a device with 2DEG and 2DHG reservoirs under 7 μW of power and more than 8.2 μm cathode-anode distance. The latter has a pulse width of less than 3 ps FWHM, and fall time of less than 2 ps. This orders-of-magnitude increase in speed is due to the collective response of the charge reservoirs that circumvents the drift velocity limitations.

Further proof that the response is not due to the transport of charge carriers is provided by comparing the response of two devices with gap distances of 1.8 μm and 8.7 μm, respectively, at 830 nm, in FIG. 3C. The response of the device with nearly five (5) times the gap distance is practically identical to the shorter one, not only in rise time and pulse width, but also in fall time. This also shows that the 2D hole reservoir reacts in the same manner as the 3D electron reservoir with time constants that are of the order of dielectric relaxation time, implying that the hole effective mass (used to determine the drift velocity in response to the electric field's force) is rather immaterial.

This important characteristic is to be expected since the effective mass is derived from force-velocity relationship of the energy-momentum (E-K) relation, while here transfer of energy is the collective response of the medium. By analogy, this experiment is similar to kicking a ball at one end of a long row of balls in contact with each other and observing the last ball move. Obviously the first ball has not travelled the distance hence its velocity or mass does not enter calculations, rather it is the transfer of energy through the line of balls that has transported the information and caused motion of the last ball.

Device Sensitivity—Extreme sensitivity is expected from the picture of a reservoir being perturbed by small excitation, similar to observing the ripples caused by a drop of water on a serene lake. Response to ˜400 fs pulses with 1.5, 7, and 54 μW of average optical power under 2V bias at 830 nm, shown in FIG. 3D, verify this expectation. The 1.5-μW light pulse of 400 fs duration, repeated at 76 MHz and chopped at 50% duty cycle, corresponds to roughly 4×10⁻¹⁴ Joules of energy, or equivalently, 167,000 photons at wavelength of 830 nm. The 30% reflectivity from AlGaAs surface and the 10% reflected by the metal electrodes, results in detection of an incident flux of 105,000 photons. Moreover, nearly 90% of these photons penetrate through the ˜110 nm thick GaAs absorption layer. This means that 10,500 photons are absorbed, to produce a 6.5-ps wide and 1.5-mV tall pulse, with an identical pulse propagating in each half of the 80-ohm transmission line, resulting in N=I*dt/q=1500 electrons per pulse. Thus, nearly one electron leaves the device for every 7 absorbed photons.

The data presented in FIGS. 3A-3D proves the great promise of optoplasmonic devices offering unprecedented sensitivity and speed. Single reservoir of 2DEG was used to facilitate current transport between cathode and anode of a heterojunction MSM. The key to the successful design and operation of the present devices was in the realization that holes should also be confined so as not to obscure the device behavior. Keeping the device in quasi equilibrium was necessary. As FIG. 2A shows, even without an applied bias, as low as 1.2 m of optical power is detected with a FWHM of—2.5 ps, while in other experiments, fast response was measured with 250 nW of optical power.

Dilute Nitride for Extension to 1310/1550 nm—Dilute nitrides technology attracted considerable attention when it was shown that the substitution of the group V anions in conventional III-V compounds with small amounts of nitrogen leads to dramatic changes of the electronic properties. Most importantly this resulted in a dramatic reduction of the energy band gap. This development made it possible to produce III-V alloy InGaAsN that would have band gap that is suitable for operating in the long-wavelength optical communication ranges of 1310 nm, or 1550 nm using a host substrate of GaAs. Edge-emitting lasers (EELs) and vertical-cavity surface emitting lasers (VCSELs) were demonstrated while such devices could previously be only made in the smaller wafer and much more expensive InP technology. As a result, significant investment is made by MBE, and MOCVD companies to show suitability of this process for volume production.

A concomitant factor in addition of small amounts of nitrogen to the host is a significant reduction in electron effective mass and a significant decrease in electron mobility. This means that large carrier concentrations can be achieved in DN material, but they will have very low mobility and herein is the exact match of the proposed opto-plasmonic technology wherein charge density waves, rather than drift limited current flow carries the information.

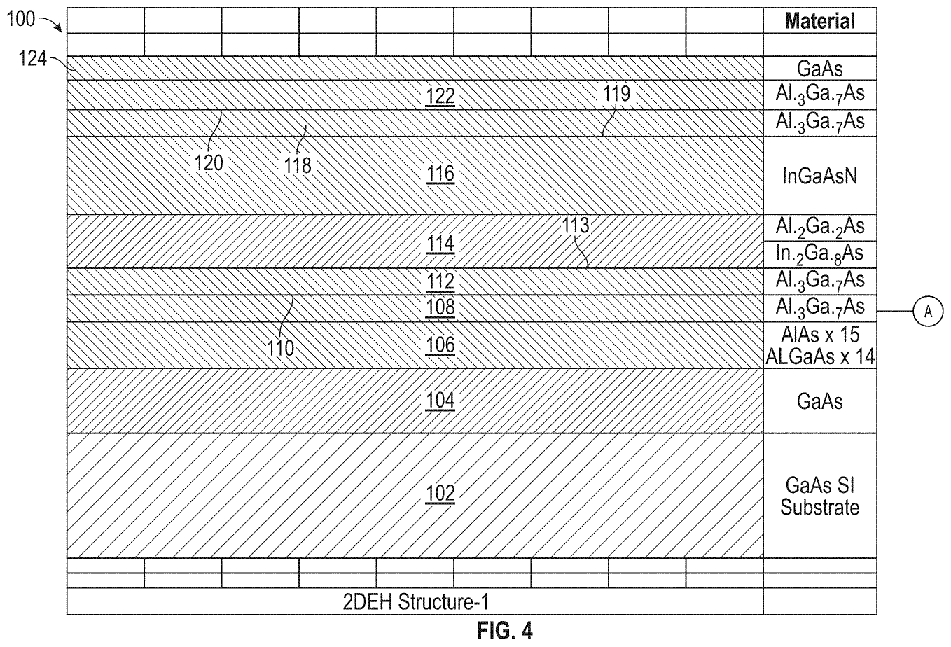

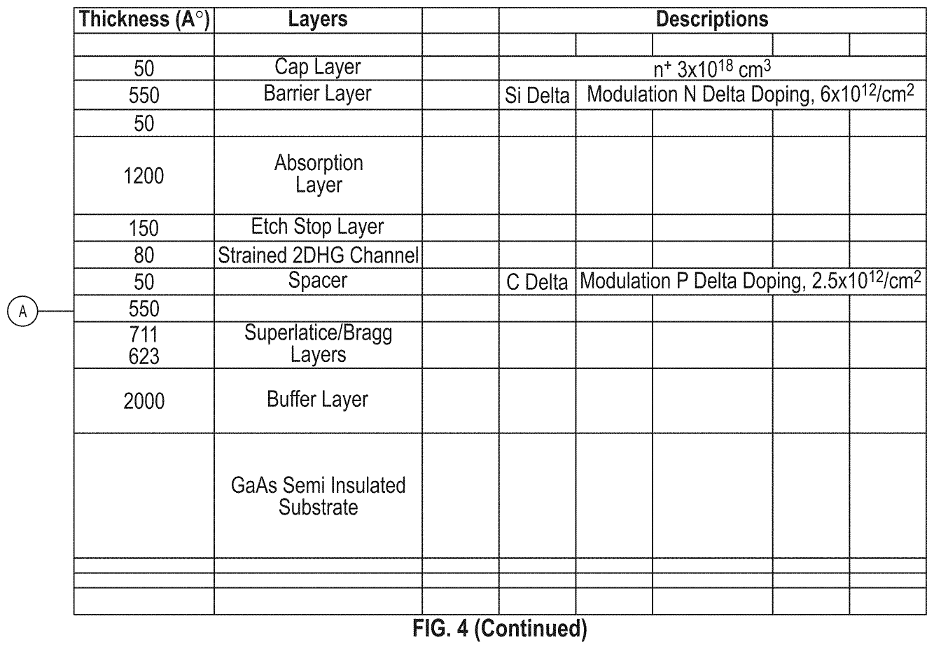

An exemplary embodiment of a 2DEHG DN-MSM device 100 according to the present invention is shown in FIG. 4. Device 100 is a single wafer with one DN layer and can be used for a 1310 nm or a 1550 nm bandgap. Device 100 includes a barrier enhancement layer 122, and provides a strong vertical field, with 2D GaAs and 2D hole gas reservoirs in GaAs.

Device 100 is constructed from multiple layers and starts with a GaAs substrate 102. A GaAs buffer layer 104 is applied over substrate 102. In an exemplary embodiment, layer 104 can be about 2,000 Angstroms)(A°) thick. Next, a superlattice/Bragg layer 106 is applied over layer 104. Layer 106 can be constructed from alternating layers of AlAs and AlGaAs. In an exemplary embodiment, 15 layers of AlAs and 14 layers of AlGaAs are used, with the thickness of each AlAs layers being 1,165 A° and the thickness of each AlGaAs being 1,020 A°. These layer thicknesses are designed to reflect the incident light radiation, at 1310 nm in this embodiment, hence produce a resonant cavity, for higher quantum efficiency. Such detectors are known as resonant cavity enhanced (RCE) photodetectors.

A next layer 108 of Al_{.3}Ga_{.7}As is applied over layer 106. The mole fraction of Al equaling x=0.3 and Ga equaling (1-0.3)=0.7 are chosen so that the ternary AlₓGa₍₁₋ₓ₎ As lattice matches to GaAs. Layer 108 can be 550 A° thick. Layer 108 can be modulation doped using p-type dopant such as carbon. The doping can be applied only to a few atomic layers 5-15 A°, resulting in what is known as delta doping with sheet dopant density of 2.5×10¹²/cm².

A second GaAs 110 can be applied over layer 108 with a second layer 112 of Al_{.3}Ga_{.7}As applied on top of layer 110. Layer 112 can be 50 A° thick. A layer 114 of In_{.2}Ga_{.8}As forms a strained 2DHG channel 113 over top of layer 112 with a heterojunction 115 between spacer 112 and 2DHG channel 113, with an etch stop layer constructed from Al_{.8}Ga_{.2}As applied over the 2DHG channel 113. The In_{.2}Ga_{.8}As channel can be 80 A° thick, while the Al_{.8}Ga_{.2}As layer can be 200 A° thick. This construction produces a 2DHG in layer 114.

A 2,100 A° thick absorption layer 116 of dilute nitride InGaAsN can be applied over layer 114.A next layer 118 of Al_{.3}Ga_{.7}As can be applied over layer 116 and can be 50 Ao thick. A spacer layer 120 is n-type delta-doped with Si, and consists of 1-3 atomic layers, with a sheet electron density of about 6×10¹²/cm². This doping produces a 2DEG at the heterojunction 119 between absorption layer 116 and the spacer layer 120. A so-called barrier enhancement layer 122 of Al_{.3}Ga_{.7}As having a thickness of 550 A° is produced on top of this layer 120. Heterojunctions 115 and 119 also landscape an internal electric field in the absorption layer 116 that forces optically generated electron hole pairs towards the 2DEG and 2DHG, before the 2DEG and 2DHG recombine and disappear. This generates high sensitivity and high speed simultaneously and directs electron hole pair motion.

A cap layer 122 constructed from GaAs having a thickness of 500 A°. This layer is Silicon doped n-type with volume density of n+3×10¹⁸/cm³ and is applied over layer 120.

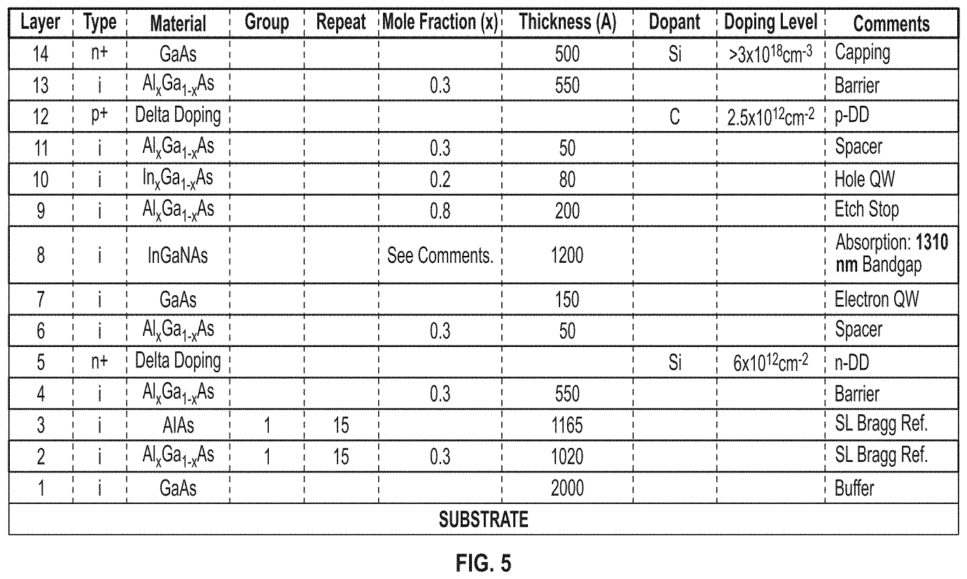

An alternative exemplary embodiment has the two-dimensional hole gas (2DHG) on top near the contacts, with 2DEG sandwiching the dilute nitride absorption region, hence designated as 2DHE-HTW device 200 according to the present invention is shown in FIG. 5. Device 200 is a single wafer with one DN layer and can be used for a 1310 nm or a 1550 nm bandgap. Device 200 is similar to device 100, but with location of electron and hole gasses reversed so that the slow moving holes are more quickly collected compared to the fast moving electrons. Configurations of each layer and exemplary thicknesses are provided in FIG. 5.

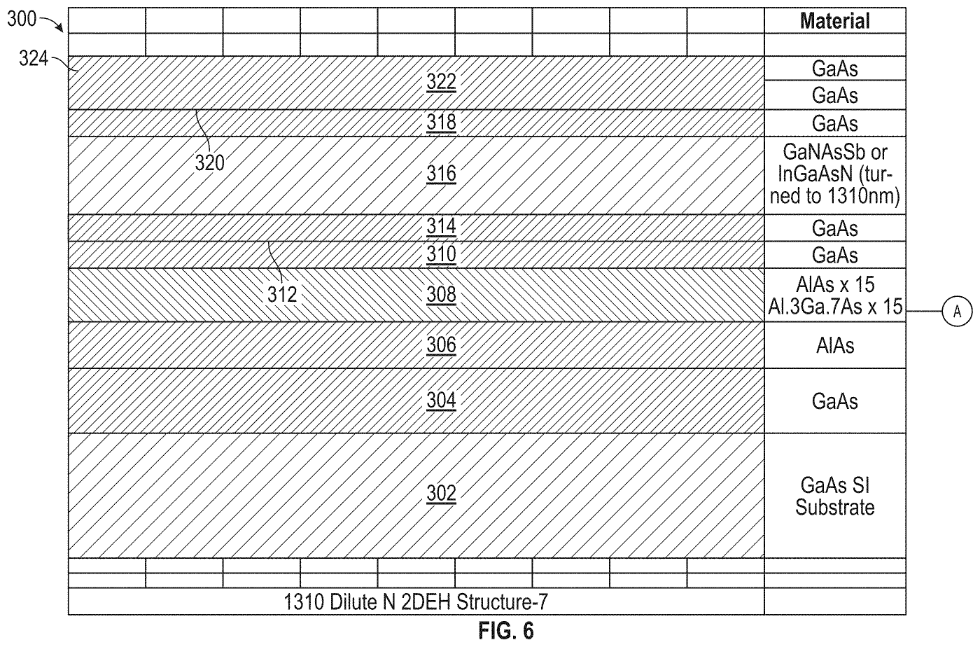

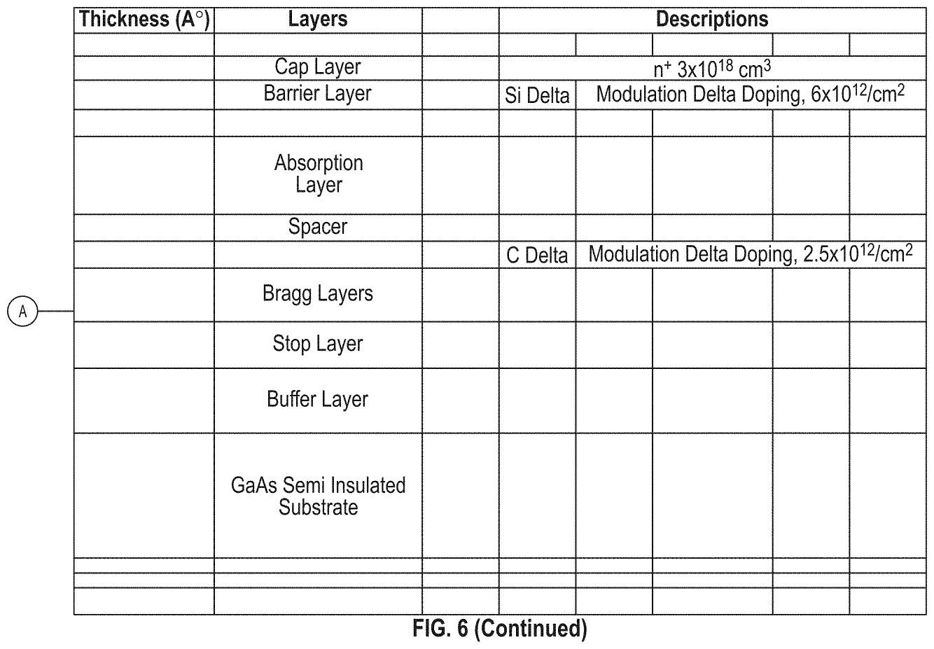

An exemplary embodiment of a 2DEHG DN device 300 according to the present invention is shown in FIG. 6. Device 300 consists of a single DN absorption layer that make heterojunctions with GaAs or AlGaAs on both sides. Doping of these wider-gap/layers produces 2DEG and 2DHG on either side of the DN absorption region.

Device 300 is constructed from multiple layers and starts with a semi-insulating GaAs substrate 302. A GaAs buffer layer 304 is applied over substrate 302. In an exemplary embodiment, layer 304 can be about 2,000 A° thick.

An etch-stop layer 306 of AlAs is applied over layer 304. Etch-stop layer 306 can be 1500 A° thick. Next, a Bragg layer 308 is applied over stop layer 306. Layer 308 can be constructed from alternating layers of AlAs and Al_{.3}Ga_{.7}As. In an exemplary embodiment, 15 layers of AlAs and 15 layers of Al_{.3}Ga_{.7}As are used, with the total thickness of the AlAs layers being 1165 A° and the total thickness of Al_{.3}Ga_{.7}As being 1020 A°.

A GaAs layer 310 is applied over layer 308. Layer 310 has a thickness of 570 A°, with p-type Delta doping such as carbon, shown in 312, of sheet density about 2.5×10¹²/cm², which provides 2DHG in DN absorption region 316. A GaAs spacer layer 314 is applied over layer 312 and has a thickness of 50 A°.

An absorption layer 316, constructed from dilute nitride, GaNAsSb or InGaAsN (tuned to 1310 nm) is applied over layer 314. Absorption layer 316 is 2100 A° thick.

A GaAs layer 318, having a thickness of 50 A°, is formed on layer 316. Layer 320 is n-type delta doped with Si having sheet density of 6×10¹² cm⁻² or more and provides the 2DEG in the absorption layer 316. A GaAs barrier layer 322 having a thickness of 550 A° is formed over layer 320. and a GaAs cap layer 324 having a thickness of 500 A° is formed over layer 322 and doped with about 3×10¹⁸ cm⁻³ n-type dopants.

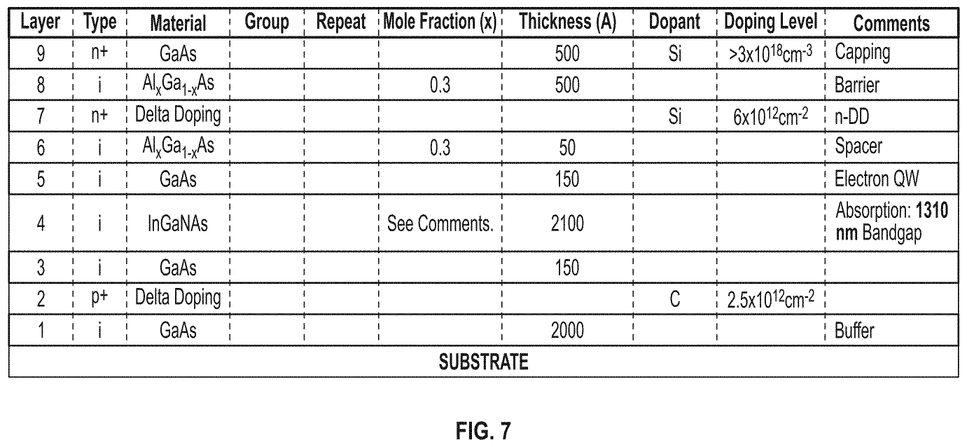

Exemplary layer structures for an alternative embodiment of 1310-DN-2DE photodetector devices are shown in FIG. 7. This embodiment is similar to FIG. 4, with the exception that it does not have provisions for producing 2DHG and only consist of a 2DEG at the top.

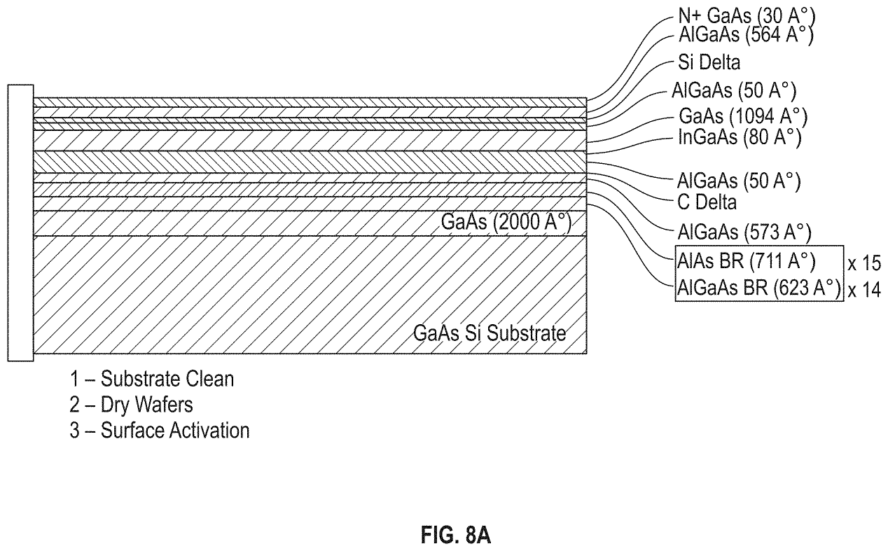

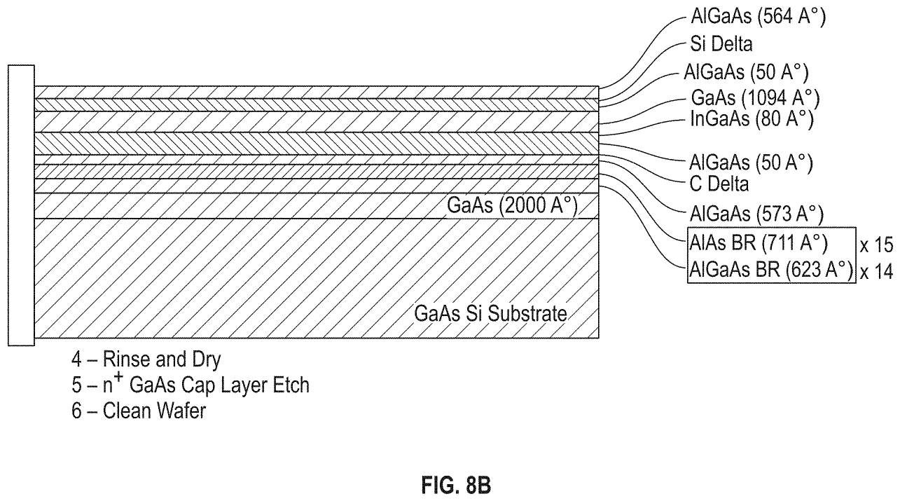

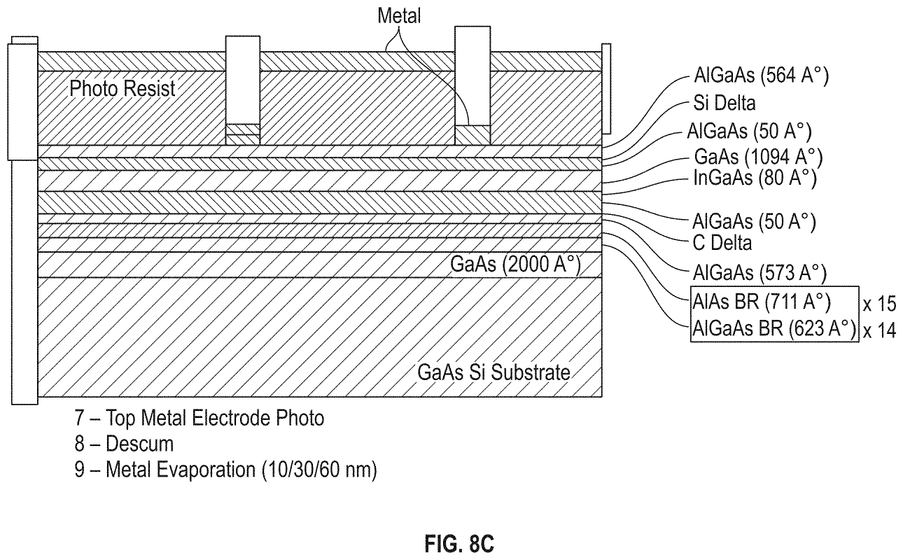

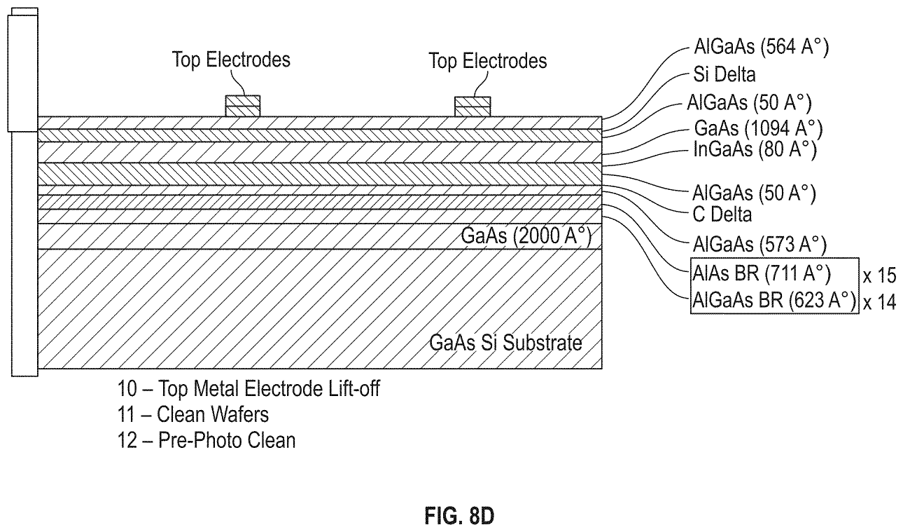

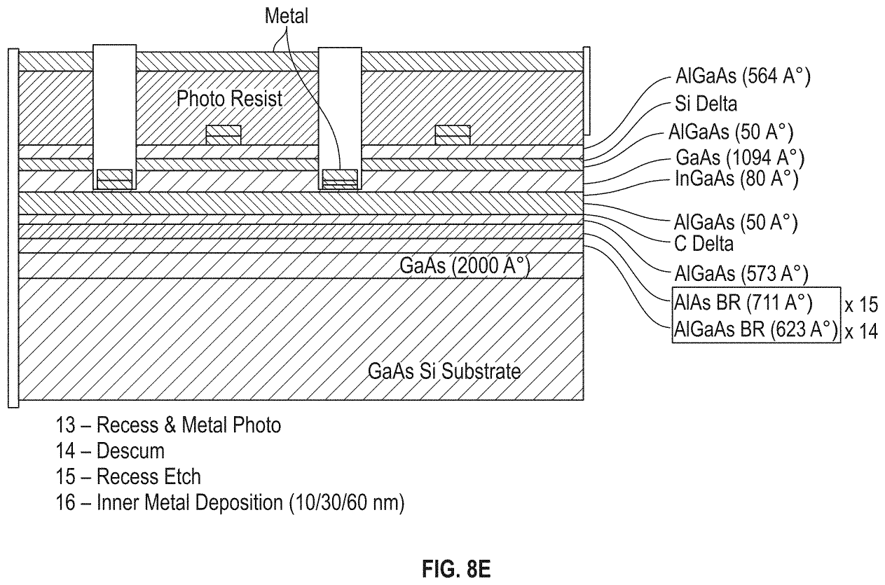

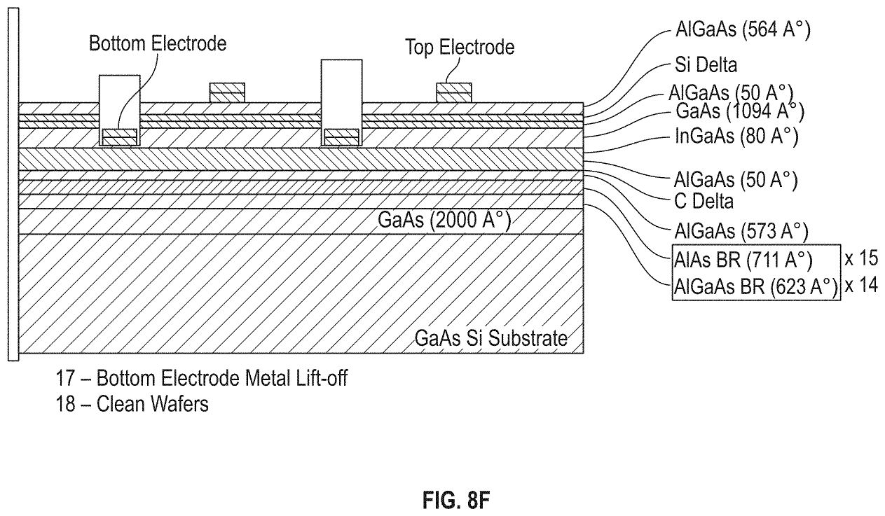

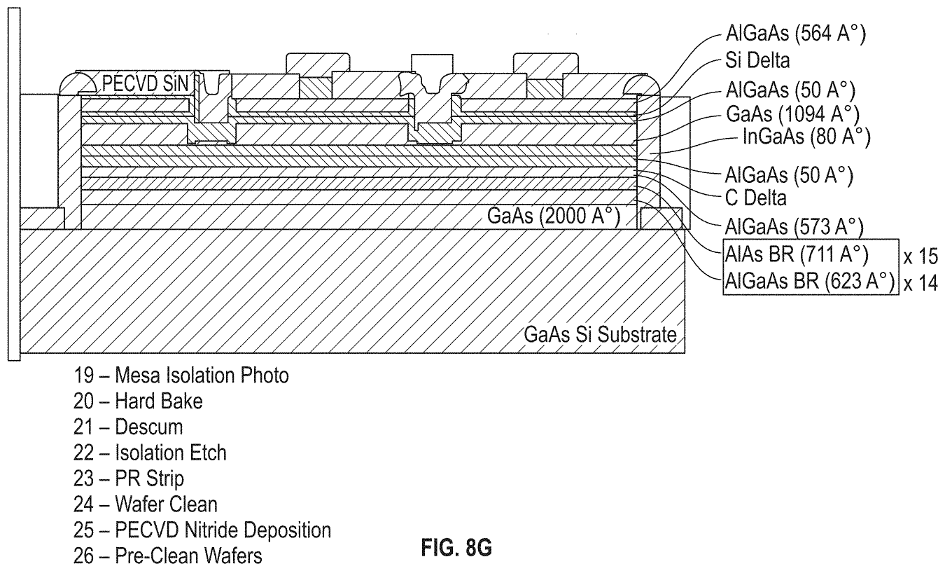

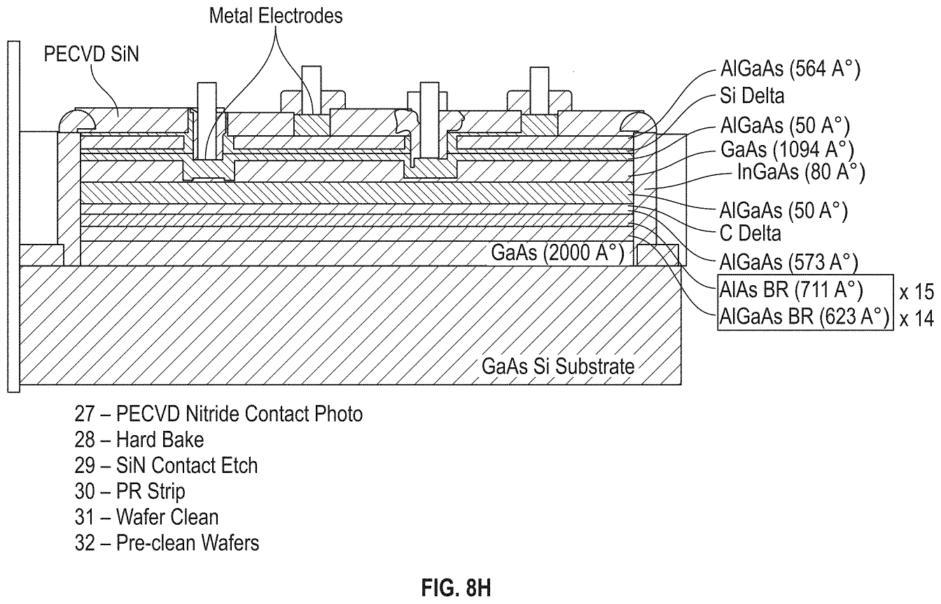

FIGS. 8A-8I show exemplary steps for processing of the devices and adding electrical contacts to a photodetector device according to the present invention. Provisions are made to etch the layer exactly so that contacts can be made directly to two-dimensional reservoirs of charge that are subsurface.

FIGS. 8A-8D show the fabrication process that results in deposition of contacts on top of the device. Referring to FIG. 8A, prior to building the detector, the substrate is cleaned and dried. The surface is then activated. Referring to FIG. 8B, after a rinse and dry, the n+ GaAs cap layer is etched. The wafer is then cleaned. Referring to FIG. 8C, a top metal electrode is photoetched, and descummed to remove thin residual layers of photoresist areas following photoresist development, followed by metal evaporation in 10, 30, and 60 nm layers. Referring to FIG. 8D, the top metal electrode is lifted-off, the wafer is cleaned, and a pre-photoetch clean is performed.

FIGS. 8E-8I show the several steps required to etch, passivate, isolate, and finally deposit recessed contacts directly on subsurface reservoirs of charge. Referring to FIG. 8E, the recess and metal are photoetched and descummed. The recess is then etched and an inner metal layer of 10 nm, 30 nm, and 60 nm is deposited. Referring to FIG. 8F, the bottom electrode meta is lifted off and the wafer is again cleaned.

Referring to FIG. 8G, a mesa isolation layer is photoetched and then hard baked and descummed and then isolation etched. Next, the photoresist is stripped and the wafer is cleaned. Nitride is deposited via plasma-enhanced chemical vapor deposition (PECVD) and the wafer is pre-cleaned. Referring to FIG. 8H, the PECVD nitride contact layer is photoetched and the wafer is hard baked. A SiN contact is then etcged with a subsequent photoresist stripping. The wafer is cleaned and then pre-cleaned. Referring to FIG. 8I, metal pads are photoetched and descummed. The pad metal is deposited and excess is lifted off. The wafer is then cleaned and annealed. Next, the wafer is tested for quality.

FIG. 9 is a top view photograph of an array of fabricated devices according to the present invention with one being probed for optoelectronic measurements.

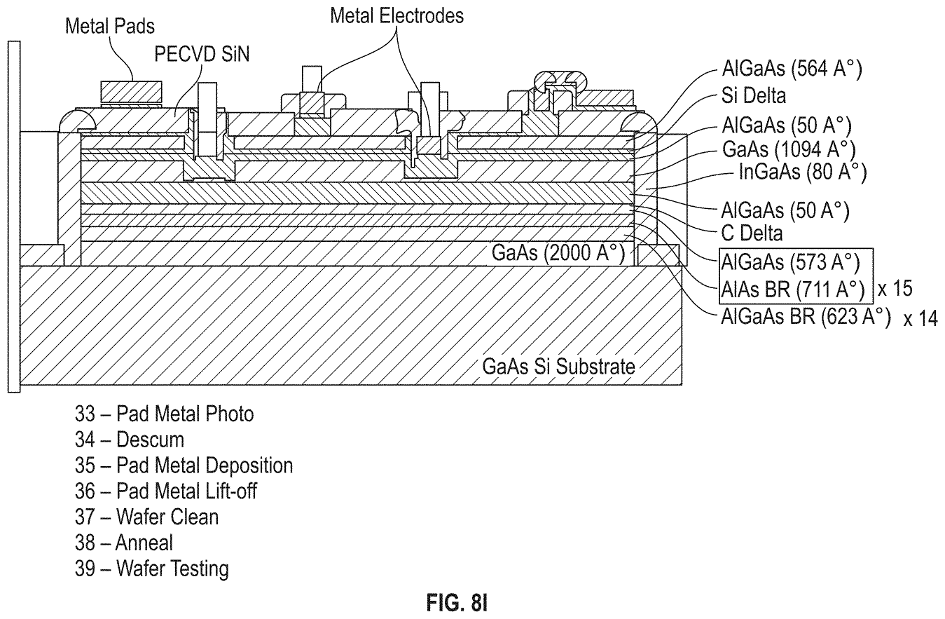

FIG. 10 is a graph of current-voltage relation of a device according to the present invention under 1310 nm laser light showing sensitivity and very low dark current, resulting in a high dynamic range.

FIG. 11 is a graph of photocurrent spectra of devices of structures 100 and 300 and the structure of FIG. 7 being compared, with all devices operating within the O-band (Original band: 1260 nm to 1360), being formed on GaAs substrates which do not absorb light with wavelength higher that 830 nm.

It will be further understood that various changes in the details, materials, and arrangements of the parts which have been described and illustrated in order to explain the nature of this invention may be made by those skilled in the art without departing from the scope of the invention as expressed in the following claims.

We claim:

1. A photodetector comprising:
a GaAs substrate;
a GaAs buffer layer on top of the substrate;
a plurality of alternating Bragg layers of AlAs and AlGaAs on top of the buffer layer; and
a plurality of XxGaAsYy layers on top of the alternating layers, wherein Xx and Yy is one of nothing, Al, In, N, and Sb.

2. The photodetector according to claim 1, wherein the plurality of alternating layers comprises fifteen layers of AlAs and fourteen layers of AlGaAs.

3. The photodetector according to claim 1, further comprising a GaAs cap layer on top of the XxGaAs layers.

4. The photodetector according to claim 1, wherein the plurality of XxGaAs layers comprise, from bottom to top:
a C Delta layer;
a spacer layer;
a strained 2DHG channel;
an etch stop layer;
an absorption layer;
a spacer layer; and
a barrier layer.

5. The photodetector according to claim 4, wherein the C delta layer, the spacer layer, and the spacer layer are Al_{.3}Ga_{.7}As layers.

6. The photodetector according to claim 4, wherein the strained 2DHG channel is an In_{.2}Ga_{.8}As layer.

7. The photodetector according to claim 1, further comprising an AlAs stop layer between the buffer layer and the Bragg layers.

8. The photodetector according to claim 1, wherein Xx is In.

9. The photodetector according to claim 1, wherein Yy is N.

10. The photodetector according to claim 1, wherein Yy is Sb.

11. The photodetector according to claim 1, wherein a first of the XxGaAsYy layers comprises Al_{.3}Ga_{.7}As and a second of the XxGaAsYy layers comprises In_{.2}Ga_{.8}As, and a 2D hole gas (2DHG) heterjunction is formed between the first XxGaAsYy and the second XxGaAsYy layer.

12. The photodetector according to claim 11, wherein a third of the XxGaAsYy layers comprises InGaAsN and a fourth of the XxGaAsYy layers comprises Al_{.3}Ga_{.7}As, and a 2D electron gas (2DEG) heterojunction is formed between the third XxGaAsYy layer and the fourth XxGaAsYy layer.

13. The photodetector according to claim 12, wherein an absorption layer is formed between the 2DHG and 2DEG heterojuctions.

14. The photodetector according to claim 13, wherein an internal electric field is formed in the fourth XxGaAsYy layer, the electric filed forcing ptically generated electron hole pairs towards the 2DEG and 2DHG heterojunctions, before the 2DEG and 2DHG heterojunctions recombine and disappear.

15. A photodetector comprising:
a substrate;
a buffer layer on top of the substrate;
a Bragg layer on top of the buffer layer;
a first Delta doping layer on top of the Bragg layer;
at least one layer on top of the first Delta doping layer;
an absorption layer on top of the at least one layer;
a second Delta layer on top of the absorption layer;
a barrier layer on top of the second Delta layer; and
a cap layer on top of the barrier layer.

16. The photodetector according to claim 15, further comprising a stop layer between the buffer layer and the Bragg layer.

17. The photodetector according to claim 15, wherein the first Delta layer is an n-type layer.

18. The photodetector according to claim 17, wherein the n-type layer comprises a Si dopant.

19. The photodetector according to claim 15, wherein the second Delta layer is a p-type dopant layer.

20. The photodetector according to claim 19, wherein the p-type layer comprises C.

21. The photodetector according to claim 14, wherein the absorption layer absorbs light energy in the 1310 nm band.

22. The photodetector according to claim 14, wherein the cap layer is constructed from GaAs having a thickness of 500 A° and is a Silicon doped n-type layer with a volume density of n+3×10¹⁸/cm³.

23. The photodetector according to claim 14, wherein the at least one layer comprises a spacer layer.

24. The photodetector according to claim 14, wherein the at least one layer comprises a strained 2DHG channel.
